(19) United States
(12) Patent Application Publication
(10) Pub. No.: US 2025/0253294 A1
(43) Pub. Date: Aug. 7, 2025

(54) TSV AS PAD

(71) Applicant: ADEIA SEMICONDUCTOR BONDING TECHNOLOGIES INC., San Jose, CA (US)

(72) Inventors: Guilian Gao, Campbell, CA (US); Bongsub Lee, Santa Clara, CA (US); Gaius Gillman Fountain, JR., Youngsville, NC (US); Cyprian Emeka Uzoh, San Jose, CA (US); Belgacem Haba, Saratoga, CA (US); Laura Wills Mirkarimi, Sunol, CA (US); Rajesh Katkar, Milpitas, CA (US)

(21) Appl. No.: 19/003,994

(22) Filed: Dec. 27, 2024

Related U.S. Application Data
(63) Continuation of application No. 18/451,674, filed on Aug. 17, 2023, now Pat. No. 12,205,926.
Application No. 18/451,674 is a continuation of application No. 16/439,360, filed on Jun. 12, 2019, now Pat. No. 11,749,645.
(60) Provisional application No. 62/684,505, filed on Jun. 13, 2018.

(51) Int. Cl. H01L 25/065; H01L 21/768; H01L 23/00; H01L 23/48; H01L 23/482; H01L 23/522

(52) U.S. Cl. CPC H01L 25/0657; H01L 21/76843; H01L 21/76895; H01L 21/76898; H01L 23/481; H01L 23/4824; H01L 23/5226; H01L 24/09; H01L 24/32; H01L 24/80; H01L 24/83; H01L 2224/08145; H01L 2224/80895; H01L 2224/80896; H01L 2225/06524; H01L 2225/06544

(57) ABSTRACT

Representative techniques and devices including process steps may be employed to mitigate the potential for delamination of bonded microelectronic substrates due to metal expansion at a bonding interface. For example, a through-silicon via (TSV) may be disposed through at least one of the microelectronic substrates. The TSV is exposed at the bonding interface of the substrate and functions as a contact surface for direct bonding.

### PRIORITY CLAIM AND CROSS-REFERENCE TO RELATED APPLICATION

This application is a continuation of U.S. patent application Ser. No. 18/451,674, filed Aug. 17, 2023, which is a continuation of U.S. patent application Ser. No. 16/439,360, filed Jun. 12, 2019, which claims the benefit under 35 U.S.C. § 119(e)(1) of U.S. Provisional Application No. 62/684,505, filed Jun. 13, 2018, which are hereby incorporated by reference in their entireties.

### FIELD

The following description relates to integrated circuits (“ICs”). More particularly, the following description relates to manufacturing IC dies and wafers.

### BACKGROUND

Microelectronic elements often comprise a thin slab of a semiconductor material, such as silicon or gallium arsenide, commonly called a semiconductor wafer. A wafer can be formed to include multiple integrated chips or dies on a surface of the wafer and/or partly embedded within the wafer. Dies that are separated from a wafer are commonly provided as individual, prepackaged units. In some package designs, the die is mounted to a substrate or a chip carrier, which is in turn mounted on a circuit panel, such as a printed circuit board (PCB). For example, many dies are provided in packages suitable for surface mounting.

Packaged semiconductor dies can also be provided in “stacked” arrangements, wherein one package is provided, for example, on a circuit board or other carrier, and another package is mounted on top of the first package. These arrangements can allow a number of different dies or devices to be mounted within a single footprint on a circuit board and can further facilitate high-speed operation by providing a short interconnection between the packages. Often, this interconnect distance can be only slightly larger than the thickness of the die itself. For interconnection to be achieved within a stack of die packages, interconnection structures for mechanical and electrical connection may be provided on both sides (e.g., faces) of each die package (except for the topmost package).

Additionally, dies or wafers may be stacked in a three-dimensional arrangement as part of various microelectronic packaging schemes. This can include stacking a layer of one or more dies, devices, and/or wafers on a larger base die, device, wafer, substrate, or the like, stacking multiple dies or wafers in a vertical or horizontal arrangement, and various combinations of both.

Dies or wafers may be bonded in a stacked arrangement using various bonding techniques, including direct dielectric bonding, non-adhesive techniques, such as ZiBond® or a hybrid bonding technique, such as DBI®, both available from Invensas Bonding Technologies, Inc. (formerly Ziptronix, Inc.), an Xperi company. The bonding includes a spontaneous process that takes place at ambient conditions when two prepared surfaces are brought together (see for example, U.S. Pat. Nos. 6,864,585 and 7,485,968, which are incorporated herein in their entirety).

Respective mating surfaces of the bonded dies or wafers often include embedded conductive interconnect structures (which may be metal), or the like. In some examples, the bonding surfaces are arranged and aligned so that the conductive interconnect structures from the respective surfaces are joined during the bonding. The joined interconnect structures form continuous conductive interconnects (for signals, power, etc.) between the stacked dies or wafers.

There can be a variety of challenges to implementing stacked die and wafer arrangements. When bonding stacked dies using a direct bonding or hybrid bonding technique, it is usually desirable that the surfaces of the dies to be bonded be extremely flat, smooth, and clean. For instance, in general, the surfaces should have a very low variance in surface topology (i.e., nanometer scale variance), so that the surfaces can be closely mated to form a lasting bond.

Double-sided dies can be formed and prepared for stacking and bonding, where both sides of the dies will be bonded to other substrates or dies, such as with multiple die-to-die or die-to-wafer applications. Preparing both sides of the die includes finishing both surfaces to meet dielectric roughness specifications and metallic layer (e.g., copper, etc.) recess specifications. For instance, conductive interconnect structures at the bonding surfaces may be slightly recessed, just below the insulating material of the bonding surface. The amount of recess below the bonding surface may be determined by a dimensional tolerance, specification, or physical limitation of the device or application. The hybrid surface may be prepared for bonding with another die, wafer, or other substrate using a chemical mechanical polishing (CMP) process, or the like.

In general, when direct bonding surfaces containing a combination of a dielectric layer and one or more metal features (e.g., embedded conductive interconnect structures) are bonded together, the dielectric surfaces bond first at lower temperatures and the metal of the features expands afterwards, as the metal is heated during annealing. The expansion of the metal can cause the metal from both bonding surfaces to join into a unified conductive structure (metal-to-metal bond). While both the substrate and the metal are heated during annealing, the coefficient of thermal expansion (CTE) of the metal relative to the CTE of the substrate generally dictates that the metal expands much more than the substrate at a particular temperature (e.g., −300C). For instance, the CTE of copper is 16.7, while the CTE of fused silica is 0.55, and the CTE of silicon is 2.56.

In some cases, the greater expansion of the metal relative to the substrate can be problematic for direct bonding stacked dies or wafers. If a metal pad is positioned over a through-silicon via (TSV), the expansion of the TSV metal can contribute to the expansion of the pad metal. In some cases, the combined metal expansion can cause localized delamination of the bonding surfaces, as the expanding metal rises above the bonding surface. For instance, the expanded metal can separate the bonded dielectric surfaces of the stacked dies.

### BRIEF DESCRIPTION OF THE DRAWINGS

The detailed description is set forth with reference to the accompanying figures. In the figures, the left-most digit(s) of a reference number identifies the figure in which the reference number first appears. The use of the same reference numbers in different figures indicates similar or identical items.

For this discussion, the devices and systems illustrated in the figures are shown as having a multiplicity of components. Various implementations of devices and/or systems, as described herein, may include fewer components and remain within the scope of the disclosure. Alternatively, other implementations of devices and/or systems may include additional components, or various combinations of the described components, and remain within the scope of the disclosure.

FIG. 1A shows a cross-section of an example substrate with bonding pads and a TSV.

FIG. 1B shows a top view of the example substrate of FIG. 1A.

FIG. 2 shows a cross-section of two example bonded substrates with bonding pads and TSVs, and example resulting delamination.

FIG. 3A shows a cross-section of an example substrate with at least one end of the TSV as a bonding surface, according to an embodiment.

FIG. 3B shows a top view of the example substrate of FIG. 3A, according to an embodiment.

FIG. 4 shows a cross-section of two example bonded substrates with at least one end of the TSV as a bonding surface, according to an embodiment.

FIG. 5 shows a cross-section of two example substrates with at least one end of the TSV as a bonding surface, according to an embodiment.

FIG. 6 shows a cross-section of two example substrates with at least one end of the TSV as a bonding surface, the bonding surfaces having an uneven surface, according to an embodiment.

FIGS. 7-13 show a cross-section of an example substrate with at least one end of the TSV as a bonding surface, illustrating an example backside process of the substrate, according to an embodiment.

FIG. 14 shows a diagram of example TSVs used for heat management of a die, according to various embodiments.

FIG. 15 is a text flow diagram illustrating an example process of forming a microelectronic assembly to reduce or eliminate delamination of the bonded substrates, according to an embodiment.

### SUMMARY

Representative techniques and devices are disclosed, including process steps for preparing various microelectronic devices for bonding, such as for direct bonding without adhesive. In various embodiments, techniques may be employed to mitigate the potential for delamination due to metal expansion, particularly when a TSV or a bond pad over a TSV is presented at the bonding surface of one or both devices to be bonded. For example, in one embodiment, the TSV may extend partially or fully through the substrate of the device, and at least one end of the TSV is exposed at a bonding surface of the device. For instance, the exposed end of the TSV is prepared and used as a bonding surface or in place of a bonding pad for the device.

When using surface preparation processes such as CMP to prepare the bonding surface of the substrate, an exposed metal end of the TSV at the bonding surface can become recessed relative to the dielectric, due to the softer material of the TSV relative to the material of the dielectric. A larger diameter TSV may become recessed to a greater degree (e.g., a deeper recess) than a smaller diameter TSV. In such an embodiment, the recess of the end surface of the TSV provides room for the metal expansion of the TSV during heated annealing, which can reduce or eliminate delamination that could occur otherwise.

In various implementations, an example process includes providing a conductive via through a first substrate having a first bonding surface. The conductive via extends from the first bonding surface at least partially through the first substrate. The process includes exposing the conductive via from a surface opposite the first bonding surface, and forming a second bonding surface with the conductive via at or recessed relative to the second bonding surface.

In vanous embodiments, the process includes reducing or eliminating delamination of bonded microelectronic components by selecting the conductive via and using at least one end of the conductive via as a bonding contact surface for direct bonding (e.g., DBI).

Additionally or alternatively, the back side of the first substrate may also be processed for bonding. One or more insulating layers of preselected materials may be deposited on the back side of the first substrate to provide stress relief when the back side of the first substrate is to be direct bonded.

Further, the conductive via, as well as other conductive vias within the first substrate may be used to direct or transfer heat within the first substrate and/or away from the first substrate. In some implementations, the thermal transfer conductive vias may extend partially or fully through a thickness of the first substrate and may include a thermally conductive barrier layer. In such examples, barrier layers normally used around the conductive vias that tend to be thermally insulating may be replaced with thermally conductive layers instead. In various implementations, some conductive vias may be used for signal transfer and thermal transfer.

In an embodiment, a microelectronic assembly comprises a first substrate having a front side and a back side, where the back side has a bonding surface comprising a nonconductive bonding layer and a conductive via. A second substrate has a front side and a back side, and the front side includes a nonconductive bonding layer and a conductive feature. The front side of the second substrate is direct bonded to the back side of the first substrate such that the conductive pad contacts to the conductive feature. An exposed end of the conductive via comprises a contact surface suitable for direct metal-to-metal bonding without an intervening material.

Various implementations and arrangements are discussed with reference to electrical and electronics components and varied carriers. While specific components (i.e., dies, wafers, integrated circuit (IC) chip dies, substrates, etc.) are mentioned, this is not intended to be limiting, and is for ease of discussion and illustrative convenience. The techniques and devices discussed with reference to a wafer, die, substrate, or the like, are applicable to any type or number of electrical components, circuits (e.g., integrated circuits (IC), mixed circuits, ASICS, memory devices, processors, etc.), groups of components, packaged components, structures (e.g., wafers, panels, boards, PCBs, etc.), and the like, that may be coupled to interface with each other, with external circuits, systems, carriers, and the like. Each of these different components, circuits, groups, packages, structures, and the like, can be generically referred to as a “microelectronic component.” For simplicity, unless otherwise specified, components being bonded to another component will be referred to herein as a “die.”

This summary is not intended to give a full description. Implementations are explained in more detail below using a plurality of examples. Although various implementations and examples are discussed here and below, further implementations and examples may be possible by combining the features and elements of individual implementations and examples.

### DETAILED DESCRIPTION

### Overview

Referring to FIG. 1A (showing a cross-sectional profile view) and FIG. 1B (showing a top view), patterned metal and oxide layers are frequently provided on a die, wafer, or other substrate (hereinafter “die 102”) as a hybrid bonding, or DBI®, surface layer. A representative device die 102 may be formed using various techniques, to include a base substrate 104 and one or more insulating or dielectric layers 106. The base substrate 104 may be comprised of silicon, germanium, glass, quartz, a dielectric surface, direct or indirect gap semiconductor materials or layers or another suitable material. The insulating layer 106 is deposited or formed over the substrate 104, and may be comprised of an inorganic dielectric material layer such as oxide, nitride, oxynitride, oxycarbide, carbides, carbonitrides, diamond, diamond like materials, glasses, ceramics, glass-ceramics, and the like.

A bonding surface 108 of the device wafer 102 can include conductive features such as contact pads 110, traces 112, and other interconnect structures, for example, embedded into the insulating layer 106 and arranged so that the conductive features 110 from respective bonding surfaces 108 of opposing devices can be mated and joined during bonding, if desired. The joined conductive features 110 can form continuous conductive interconnects (for signals, power, etc.) between stacked devices.

Damascene processes (or the like) may be used to form the embedded conductive features 110 in the insulating layer 106. The conductive features 110 may be comprised of metals (e.g., copper, etc.) or other conductive materials, or combinations of materials, and include structures, traces, pads, patterns, and so forth. In some examples, a barrier layer may be deposited in the cavities for the conductive features 110 prior to depositing the material of the conductive features 110, such that the barrier layer is disposed between the conductive features 110 and the insulating layer 106. The barrier layer may be comprised of tantalum, for example, or another conductive material, to prevent or reduce diffusion of the material of the conductive features 110 into the insulating layer 106. After the conductive features 110 are formed, the exposed surface of the device wafer 102, including the insulating layer 106 and the conductive features 110 can be planarized (e.g., via CMP) to form a flat bonding surface 108.

Forming the bonding surface 108 includes finishing the surface 108 to meet dielectric roughness specifications and metallic layer (e.g., copper, etc.) recess specifications, to prepare the surface 108 for direct bonding. In other words, the bonding surface 108 is formed to be as flat and smooth as possible, with very minimal surface topology variance. Various conventional processes, such as chemical mechanical polishing (CMP), dry or wet etching, and so forth, may be used to achieve the low surface roughness. These processes provides the flat, smooth surface 108 that results in a reliable bond.

In the case of double-sided dies 102, a patterned metal and insulating layer 106 with prepared bonding surfaces 108 may be provided on both sides of the die 102. The insulating layer 106 is typically highly planar (usually to nm-level roughness) with the metal layer (e.g., embedded conductive features 110) at or recessed just below the bonding surface 108. The amount of recess below the surface 108 of the insulating layer 106 is typically determined by a dimensional tolerance, specification, or physical limitation. The bonding surfaces 108 are often prepared for direct bonding with another die, wafer, or other substrate using a chemical-mechanical polishing (CMP) step and/or other preparation steps.

Some embedded conductive features or interconnect structures may comprise metal pads 110 or conductive traces 112 that extend partially into the dielectric substrate 106 below the prepared surface 108. For instance, some patterned metal (e.g., copper) features 110 or 112 may be about 0.5-2 microns thick. The metal of these features 110 or 112 may expand as the metal is heated during annealing. Other conductive interconnect structures may comprise metal (e.g., copper) through silicon vias (TSVs) 114 or the like, that extend normal to the bonding surface 108, partly or fully through the substrate 102 and include a larger quantity of metal. For instance, a TSV 114 may extend about 50 microns, depending on the thickness of the substrate 102. The metal of the TSV 114 may also expand when heated. Pads 110 and/or traces 112 may or may not be electrically coupled to TSVs 114, as shown in FIG. 1A.

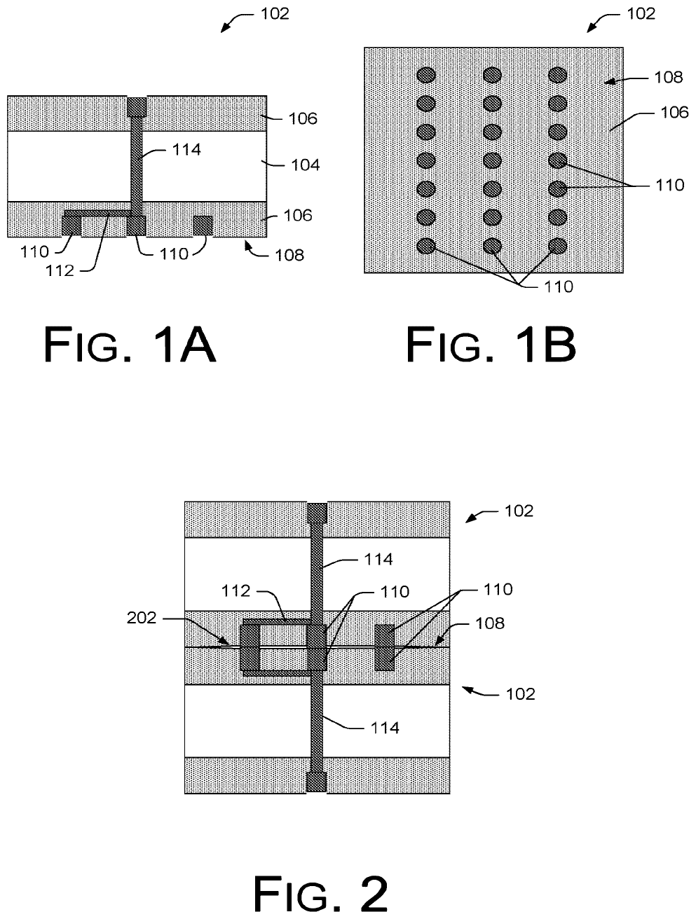

Referring to FIG. 2, dies 102 may be direct bonded, for instance, without adhesive to other dies 102 with metal pads 110, traces 112, and/or TSVs 114. If a metal pad 110 is positioned over a TSV 114 (overlapping and physically and electrically coupled to the TSV 114), the expansion of the TSV 114 metal can contribute to the expansion of the pad 110 metal. In some cases, the combined metal expansion can cause localized delamination 202 of the bonding surfaces at the location of the TSV 114 (or TSV 114/pad 110 combination), as the expanding metal rises above the bonding surface 108. For instance, the expanded metal can separate the bonded dielectric surfaces 108 of the stacked dies 102.

### EXAMPLE EMBODIMENTS

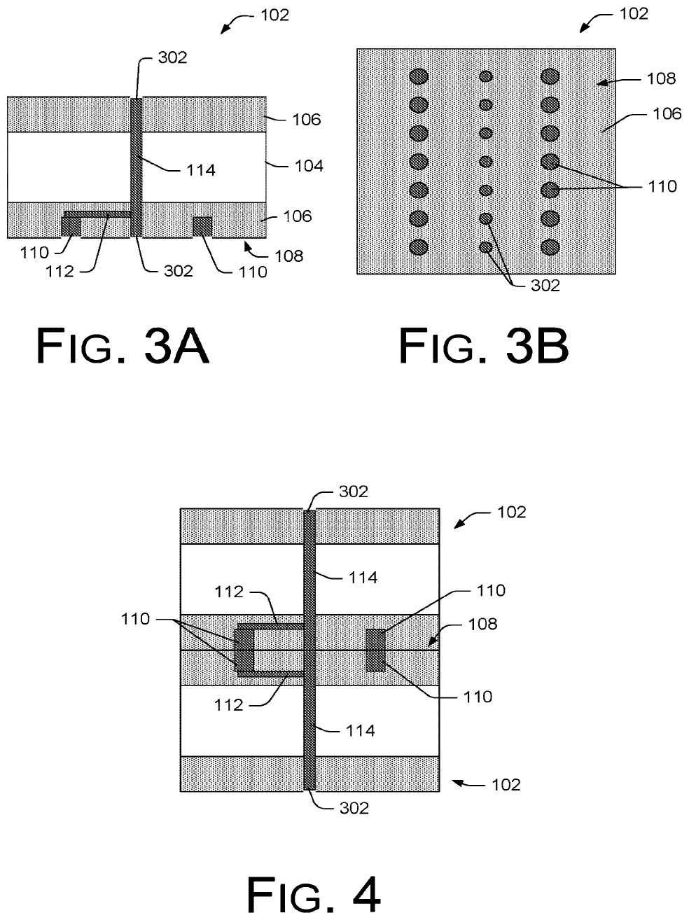

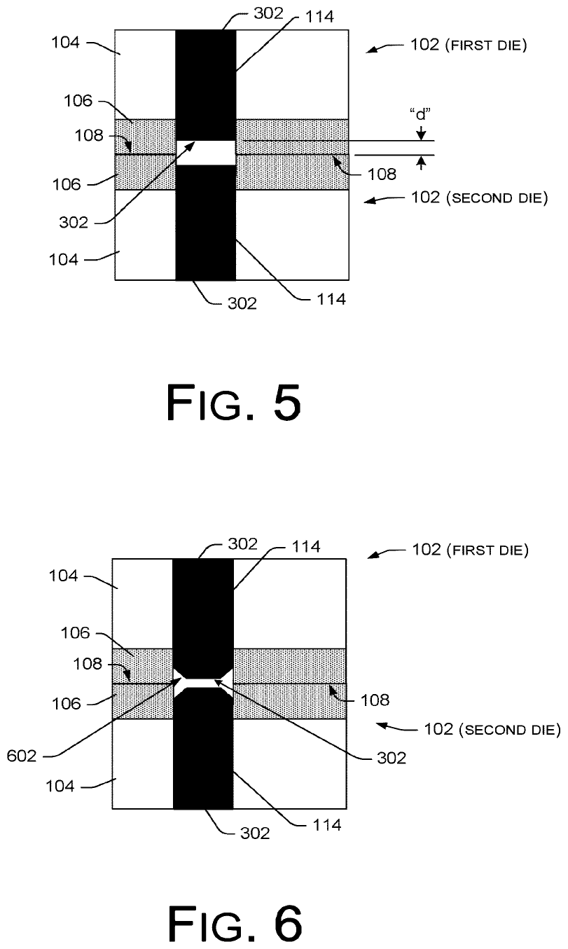

Referring to FIGS. 3A-6, in various embodiments, techniques may be employed to mitigate the potential for delamination due to metal expansion. For example, in one embodiment, as shown in FIGS. 3A and 3B, a TSV 114 may be extended through the base layer 104 of the die 102, and through one or more insulating layers 106 to at least one bonding surface 108. An end 302 (or both ends 302) of the TSV 114 may be exposed at the bonding surface(s) 108 of the die 102 and used as a contact surface for direct bonding (e.g., DBI). In other words, the contact surface 302 of the TSV can be exposed through the dielectric layer 106 at the bonding surface, prepared (e.g., planarized, etc.), and used in place of a direct bonding pad (instead of a contact pad 110).

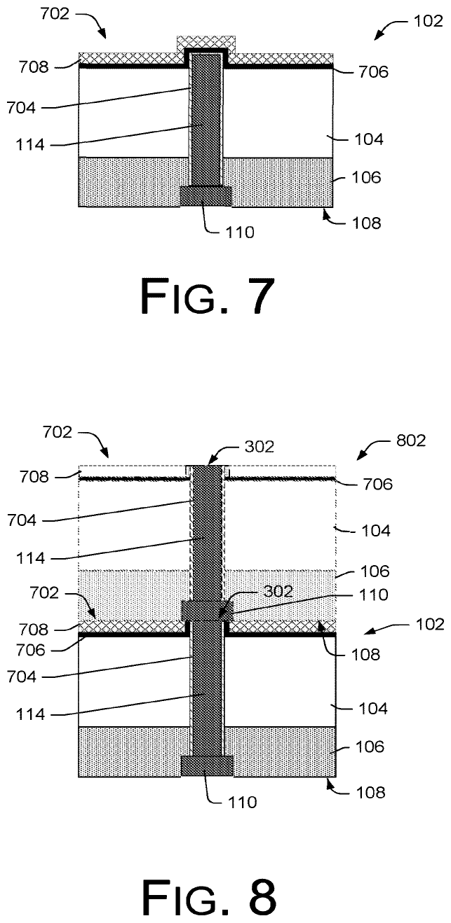

Referring to FIG. 4, in various implementations, using an end surface 302 of the TSV 114 as a bonding surface can reduce or eliminate delamination of bonded dies 102, when the dies 102 are heat annealed and the metal of the TSV 114 and the contact pads 110 expand. In the implementations, the metal expansion of the TSV 114 may be taken into consideration, based on the volume of the TSV 114. Accordingly, a predetermined recess “d” in the end surface 302 of the TSV 114 (as shown in FIG. 5, for example) can be sufficient to provide room for the material expansion of the TSV 114.

In various embodiments, TSVs 114 used as direct bonding contact structures may have diameters that are larger or smaller by a preselected amount, than other TSVs 114 disposed elsewhere within the die 102. In an embodiment, the size of the TSVs 114 are selected or formed by estimating an amount that the material of the TSV 114 will expand when heated to a preselected temperature (−300°), based on a volume of the material of the TSV 114 and a coefficient of thermal expansion (CTE) of the material of the TSV 114, and predicting an amount that the material of the TSV 114 will expand when heated to the preselected temperature.

Referring to FIG. 5, in an embodiment, the end 302 of the TSV 114 is planarized along with the bonding surface 108 of the dielectric layer 106, including recessing the end 302 of the TSV 114 to have a predetermined recess depth (“d”) relative to the bonding surface 108, based on an expansion of the TSV 114 material at the predetermined temperature. In other words, the recess depth is determined based on the volume of the material of the TSV 114 and the coefficient of thermal expansion (CTE) of the material of the TSV 114.

In one embodiment, the end 302 of a TSV 114 may be selectively etched (via acid etching, plasma oxidation, etc.) to provide the desired recess depth “d” (to accommodate a predicted metal expansion). In another example, as shown at FIG. 6, the end 302 of a corresponding TSV 114 may be selected, formed, or processed to have an uneven top surface as an expansion buffer. For example, referring to FIG. 6, the end surface 302 of the TSV 114 may be formed or selectively etched to be rounded, domed, convex, concave, irregular, or otherwise non-flat to allow additional space 602 for material expansion.

The additional space 602 may be determined and formed based on the amount that the material of the TSV 114 will expand when heated. In various implementations, the end surface 302 of the TSV 114 may be formed to be uneven during deposition, or may be etched, grinded, polished, or otherwise made uneven after forming the TSV 114. In some cases, the end surface 302 of the TSV 114 may be made uneven during CMP of the bonding surface 108.

Additionally or alternately, the dielectric 106 at the bonding surface 108 around the TSV 114 can be formed or shaped to allow room for the metal of the TSV 114 to expand. In one example, a CMP process can be used to shape the surface 108 of the dielectric 106 around the TSV 114, or in other examples other processes can be used, so that the dielectric 106 around the TSV 114 includes a recess or other gap that provides room for metal expansion. In an embodiment, the dielectric 106 can be recessed (e.g., with CMP) while the bonding surface 108 is being prepared. In the embodiment, the TSV 114 and the dielectric 106 may be recessed concurrently (but at different rates). For instance, the process may form erosion in the dielectric 106 around the edges of the TSV 114 while recessing the metal TSV 114.

In various embodiments, the TSV 114 is comprised of copper, a copper alloy, or the like. In a further embodiment, the materials of the TSV 114 may be varied to control metal expansion and potential resulting delamination. For instance, in some embodiments, the TSV 114 may be comprised of different conductive materials, perhaps with lower CTEs. In some embodiments the TSV 114 may be comprised of a different conductive material (with a lower CTE) than the contact pads 110. For example, the TSV 114 may be comprised of tungsten, an alloy, or the like.

In other embodiments the volume of material of the TSV 114 may be varied to control metal expansion and the potential for resulting delamination. For instance, in some embodiments, a TSV 114 with a preselected material volume (e.g., less volume of material) may be used, when this is allowable within the design specifications. The preselection of volume of the TSV 114 may be based on anticipated material expansion of the TSV 114.

Referring back to FIG. 4, after preparation of the bonding surface 108 (e.g., by CMP) the die 102 may be direct bonded, for instance, without adhesive to other dies 102 with metal pads 110, traces 112, and/or TSVs 114. The material of the TSVs 114 expand during heated annealing as mating TSVs 114 of opposite dies 102 bond to form a single conductive interconnect. However, the metal expansion does not cause delamination of the bonding surfaces when an adequate predetermined recess is provided as discussed, since the expanding metal of the TSV 114 does not exceed the space provided by the recess at the end surface 302 of the TSV 114.

For instance, if the end surface 302 of the TSVs 114 are sufficiently recessed, the expanding metal of the TSVs 114 fills the recess(es) without separating the bonded dielectric surfaces 108 of the stacked dies 102. When using surface preparation processes such as CMP to prepare the bonding surface 108 of the die 102, the TSVs 114 exposed at the bonding surface 108 can become recessed (intentionally or unintentionally) relative to the dielectric 106, due to the softness of the TSVs 114 (which may comprise copper, for instance) relative to the dielectric 106 (which may comprise an oxide, for example).

In vanous embodiments, the amount of recessing of a TSV 114 may be predictable, based on the surface preparation technique used (e.g., the chemical combination used, the speed of the polishing equipment, etc.), the materials of the dielectric layer 106 and the TSV 114, the spacing or density of the TSVs 114 (and metal pads 110), and the size (e.g., area or diameter) of the TSVs 114. In the embodiments, the area or diameter of the TSVs 114 may be selected (e.g., for a particular material) to avoid delamination of bonded dies 102 based on the recess desired and the expected metal expansion of the TSVs 114. For example, in some cases, larger diameter TSVs 114 may be selected when increased recessing is desired. This technique can result in reduced or eliminated delamination, as well as dependable mechanical coupling of the dielectric 106 and metal structures (e.g., TSVs 114) at the bonding surfaces 108 and reliable electrical continuity of the bonded metal structures.

### Additional Embodiments

FIGS. 7-13 illustrate examples of backside die 102 processing, according to various embodiments. In some implementations, where dies 102 are stacked and direct bonded without adhesive, the backside 702 of the die 102 may receive different preparation than the topside bonding surface 108, when the backside 702 is prepared for direct bonding. Instead of forming the dielectric layer 106 on the backside 702 of the die 102, the backside 702 may be prepared differently to reduce process steps, reduce manufacturing costs, or for other reasons.

In one implementation, the backside 702 is prepared so that the TSV 114 is exposed, to be used as a contact surface 302 for bonding to a conductive pad, interconnect, or other conductive bonding surface. The preparation may include depositing a thin layer of insulating material and planarizing (via CMP, for example) the backside 702 (which may include planarizing the insulating material and/or the base substrate 104) to reveal the TSV 114. In some cases, however, the expansion of the material of the TSV 114 during heated annealing can cause the insulating material and/or the substrate 104 to become damaged.

In an embodiment, as shown in FIGS. 7-13, one or more layers of material may be deposited on the backside 702 as a stress relief to prevent or eliminate damage to the substrate 104 and the die 102. The layers of material can be planarized and otherwise prepared as a bonding surface on the backside 702 of the die 102.

As shown at FIG. 7 the TSV 114 is disposed within the die 102, transverse to the bonding surface 108 of the die 102. The TSV 114 may initially extend beyond the surface of the backside 702 of the die 102. A diffusion barrier and oxide liner 704 surrounds the TSV 114 to prevent diffusion of the metal of the TSV 114 (e.g., copper) into the material of the base substrate 104 (e.g., silicon). In an embodiment, as shown at FIG. 7, another diffusion barrier 706 is deposited on the surface of the backside 702 of the die 102. In an example, the diffusion barrier 706 comprises a dielectric, such as a nitride or the like.

In various embodiments, one or more insulating layers are then deposited onto the backside 702 of the die 102 to prevent damage to the die 102 when the material of the TSV 114 expands. For example, a first layer 708, comprising a first low temperature dielectric, such as an oxide, may be deposited over the backside 702, including over the diffusion layer 706. The first oxide layer 708 may comprise a low temperature oxide bonding layer. For instance, FIG. 7 shows this scenario, and includes a formed contact pad 110 on the front side bonding surface 108 over the TSV 114.

As shown at FIG. 8, the backside 702 is planarized (via CMP, for example), including the one or more insulating layers 708 to form a flat, smooth bonding surface for direct bonding. The remaining dielectric layer 708 can assist with warpage control, balancing with the front side of the die 102. The TSV 114 is exposed by the planarizing, including a revealed contact surface 302 of the TSV 114.

Notably, when some types of low temperature oxide (e.g., silox, etc.) are used, the oxide may be less rigid and the TSV 114 may be more prone to breaking during planarization. Once planarized, the oxide is more stable. When other types of low temperature oxide (e.g., TEOS, etc.) are used, the oxide may give better support to the TSV 114, but the oxide may also relax, leaving the area around the TSV 114 higher (−1-10 nm) than the bonding surface, which can cause problems with direct bonding (e.g., DBI). As a solution to this issue, the DBI bonding layer (the layer 708, for example) is added on top of the TSV 114, as shown in FIG. 7.

A second die 802 similar or identical to the die 102 is also shown at FIG. 8, in dashed lines. The illustration of FIG. 8 shows an example of a front-to back direct bonding arrangement (without adhesive), where the second die 802 is bonded (dielectric-to-dielectric) at the front side 108 of the second die 802 to the backside 702 of the first die 102. As shown, in such an arrangement, the surface 302 of the revealed TSV 114 at the backside 702 of the first die 102 is bonded (metal-to-metal) to the conductive pad 110 at the second die 802. In alternate embodiments, the dies 102 and 802 may be bonded front-to-front, or back-to-back.

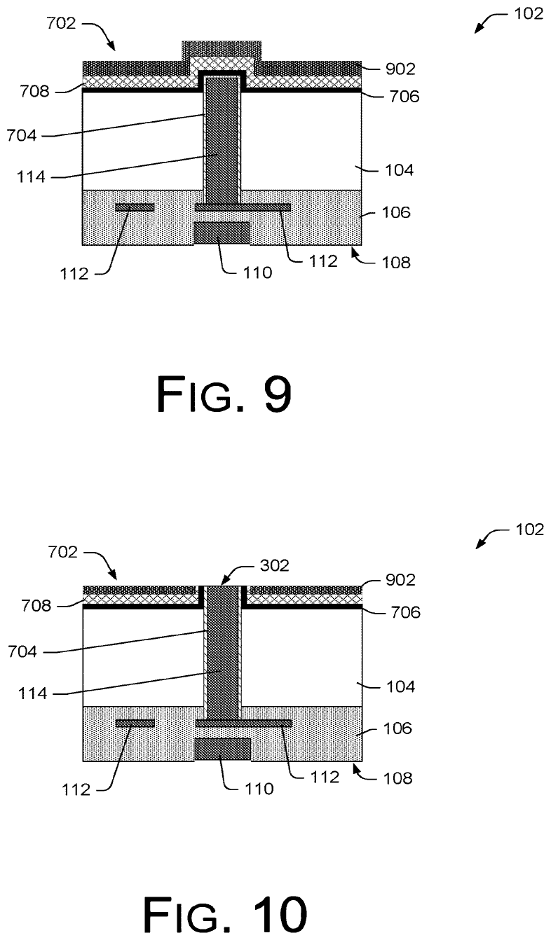

In an embodiment, as shown at FIGS. 9-10, multiple layers may be added to the backside 702 to reduce metal expansion stress at the TSV 114 and to form a backside 702 bonding surface for the die 102. As shown at FIG. 9, after deposition of the first low temperature oxide layer 708 (which also comprises the bonding layer in some implementations), a second dielectric layer 902 (which may comprise a low temperature oxide) may be deposited over the first layer 708. No barrier or adhesion layer is needed between the two oxide layers (708 and 902). In various implementations, the first layer 708 and the second layer 902 are comprised of similar or the same materials (in varying thicknesses). In other implementations, the first layer 708 and the second layer 902 are comprised of different materials. The second oxide layer 902 may have a similar or a different residue stress characteristic than the first layer 708 (for example, the first layer 708 may be compressive and the second layer 902 may be tensile, or vice versa, or both layers 708 and 902 may be compressive or tensile with similar or different values). In alternate implementations, additional insulating layers may also be deposited over the first 708 and second 902 layers.

As shown at FIG. 10, the layers 708 and 902 are planarized (e.g., CMP), revealing the TSV 114 and the end surface 302, which can function in place of a bonding pad. In an implementation, part of the second layer 902 may be left on the die 102 for warpage control.

In some embodiments, as shown in FIG. 11, the end surface 302 at the backside 702 may be formed to have an uneven or non-flat surface topology. For example, the end surface 302 may be selected, formed, or processed to have an uneven surface topology as an expansion buffer. For example, referring to FIG. 11, the end surface 302 of the TSV 114 may be formed or selectively etched to be rounded, domed, convex, concave, irregular, or otherwise non-flat to allow additional space 1102 for material expansion.

The additional space 1102 may be determined and formed based on the prediction of the amount that the material of the TSV 114 will expand when heated. In various implementations, the end surface 302 of the TSV 114 may be formed to be uneven during deposition, or may be etched, grinded, polished, or otherwise made uneven after forming the TSV 114. In some cases, the end surface 302 of the TSV 114 may be made uneven during CMP of the backside 702 bonding surface.

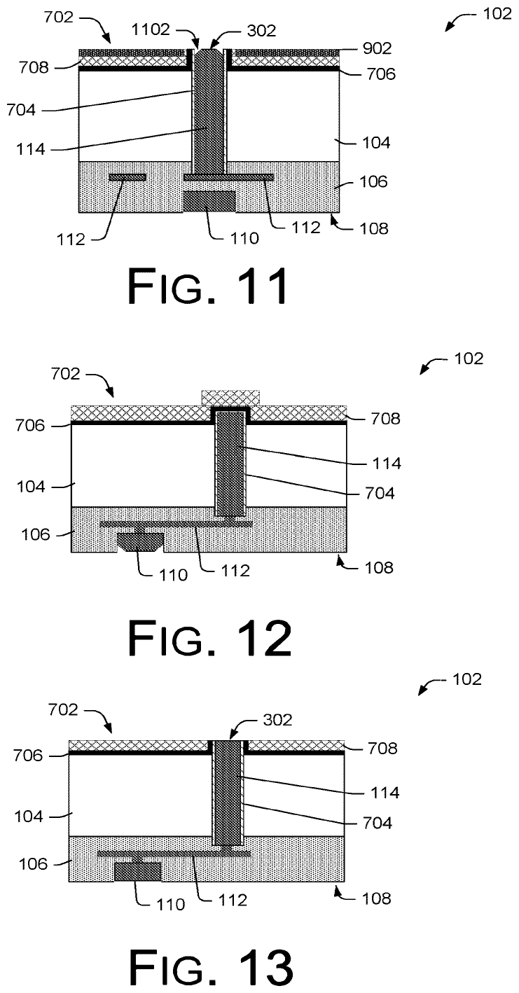

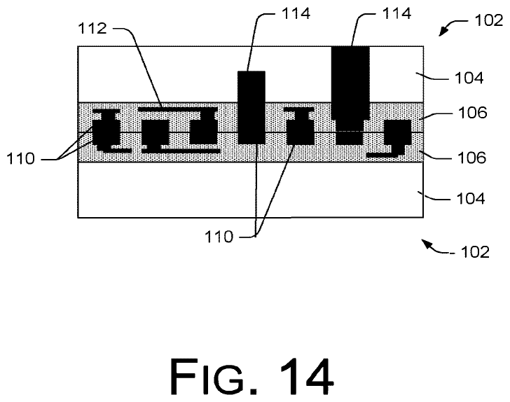

FIGS. 12-13 illustrate examples of processing the backside 702 of the die 102, when an offset contact pad 110 is disposed on the front side 108, according to various embodiments. As shown in FIGS. 12 and 13, the offset contact pad 110 may be coupled to the TSV 114 using one or more traces 112, or the like. As discussed above, one or more oxide stress layers (such as layer 708, for example) may be deposited on the backside 702 after depositing a diffusion barrier layer 706 over the backside 702. The stress layer 708 may also comprise a direct bonding layer when it is the final layer on the backside 702.

As shown in FIG. 13, the layer 708 is planarized to form a bonding surface and to reveal the TSV 114 with a smooth contact surface 302. In alternate embodiments, multiple stress layers may be deposited and planarized at the backside 702 in preparation for direct bonding.

In other embodiments, alternate techniques may be used to reduce or eliminate delamination due to metal feature expansion, and remain within the scope of the disclosure.

In various embodiments, as illustrated at FIG. 14, one or more of the TSVs 114 of a set of stacked dies 102 may be used to conduct heat in addition to or instead of electrical signals. For example, in some cases, it may not be practical or possible to attach a heat sink (or other heat transfer device) to a die 102 of a set of stacked dies 102 to alleviate heat generated by the die 102. In such cases, other techniques may be looked-for to transfer heat as desired.

In the embodiments, as shown at FIG. 14, various configurations of TSVs 114, including TSVs 114 that extend partially or fully through a die 102, may be employed to conduct heat away from the dies 102 (or away from a heat-generating portion of the dies 102). The TSVs 114 of one die 102 may be used in conjunction with TSVs 114, contact pads 110, traces 112, and the like, of the second die 102 to complete heat transfer from one die 102 to the other die 102, and so forth. The TSVs 114 of the first die 102 can be direct bonded (e.g., DBI) to the TSVs 114, contact pads 110, traces 112, and the like of the second die 102 for high performance thermal conductivity.

In an implementation, some of the TSVs 114, contact pads 110, traces 112, and the like are electrically floating or “dummy” structures, which can be used for thermal transfer. These structures may conduct heat away from a high power die 102 to another die 102 or substrate as desired. Dummy contact pads 110 may be coupled to via last or via mid thermal TSVs 114 for thermal conduction.

In the embodiments, diffusion barrier layers 704, which surround the TSVs 114 and can be thermally restrictive or thermal barriers may be replaced by diffusion barriers of a different material having some thermal conductivity (such as metal or alloy barriers, or the like).

### Example Process

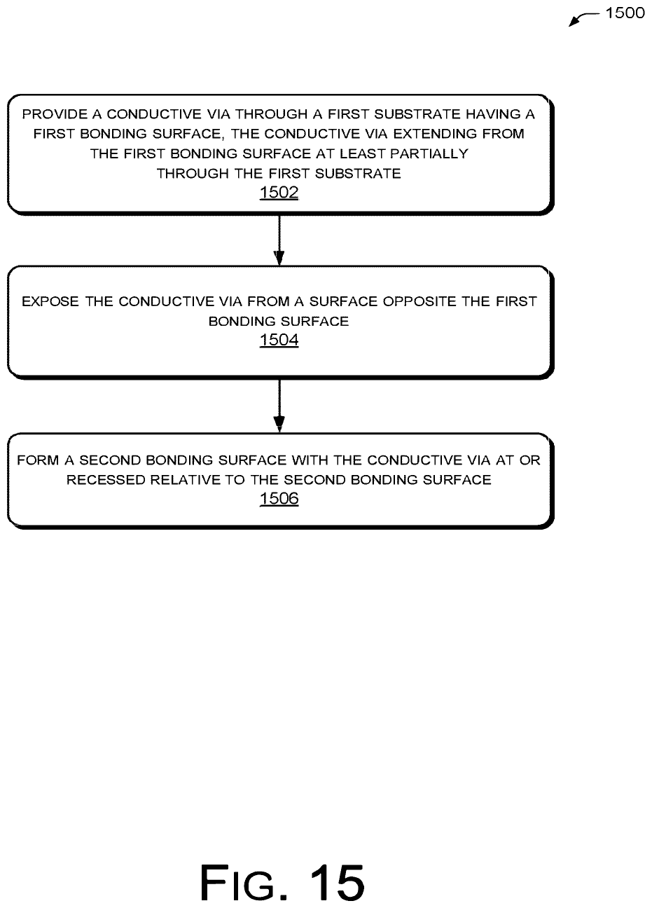

FIG. 15 illustrates a representative process 1500 for prepanng vanous microelectronic components (such as dies 102, for example) for bonding, such as for direct bonding without adhesive, while reducing or eliminating the potential for delamination due to metal expansion of embedded structures at the bonding surface. For instance, through-silicon vias (TSVs) at the bonding surface may cause delamination, particularly when coupled to contact pads, as the material of the TSVs and the contact pads expands during heated annealing. The process refers to FIGS. 1-14.

The order in which the process is described is not intended to be construed as limiting, and any number of the described process blocks in the process can be combined in any order to implement the process, or alternate processes. Additionally, individual blocks may be deleted from the process without departing from the spirit and scope of the subject matter described herein. Furthermore, the process can be implemented in any suitable hardware, software, firmware, or a combination thereof, without departing from the scope of the subject matter described herein. In alternate implementations, other techniques may be included in the process in various combinations and remain within the scope of the disclosure.

In various implementations, a die, wafer, or other substrate (a “substrate”) is formed using various techniques to include a base substrate and one or more dielectric layers. In an implementation, at block 1502, the process 1500 includes providing a conductive via (such as TSV 114, for example) through a first substrate having a first bonding surface (such as bonding surface 108, for example), the conductive via extending from the first bonding surface at least partially through the first substrate. In an implementation, the first via extends at least partially through the first substrate, normal to the first bonding surface. In one example, the first via extends through the first substrate to one or both surfaces of the first substrate.

At block 1504, the process includes exposing the conductive via from a surface opposite the first bonding surface. In an implementation, the process includes forming a recess in an exposed end of the conductive via extending a predetermined depth below the second bonding surface. For example, the recess compensates for the expansion of the conductive via during a bonding process.

In one example, the process includes forming the exposed end of the conductive via such that there is a sloped gap between the conductive via and the second bonding surface. In various examples, the uneven topology creates space for via metal expansion during heated annealing.

At block 1506, the process includes forming a second bonding surface with the conductive via at or recessed relative to the second bonding surface.

In an implementation, the process includes providing a second substrate and direct bonding the second bonding surface of the first substrate to the second substrate without an intervening adhesive. In an implementation, the process includes direct bonding the first substrate to the second substrate using a direct dielectric-to-dielectric, non-adhesive bonding technique at a bonding surface of the first substrate.

In an implementation, the second substrate further includes a conductive via extending at least partially therethrough. In another implementation, the second substrate further includes a pad over the conductive via of the second substrate, the pad contacting the conductive via of the first substrate. In an embodiment, the conductive via of the first substrate is substantially aligned with the conductive via of the second substrate.

In an alternate implementation, the conductive via is configured to remove heat from the first substrate.

In various embodiments, some process steps may be modified or eliminated, in comparison to the process steps described herein.

The techniques, components, and devices described herein are not limited to the illustrations of FIGS. 1-15, and may be applied to other designs, types, arrangements, and constructions including with other electrical components without departing from the scope of the disclosure. In some cases, additional or alternative components, techniques, sequences, or processes may be used to implement the techniques described herein. Further, the components and/or techniques may be arranged and/or combined in various combinations, while resulting in similar or approximately identical results.

### CONCLUSION

Although the implementations of the disclosure have been described in language specific to structural features and/or methodological acts, it is to be understood that the implementations are not necessarily limited to the specific features or acts described. Rather, the specific features and acts are disclosed as representative forms of implementing example devices and techniques.

1. (canceled)

2. A microelectronic structure having a back side, the microelectronic structure comprising:
a semiconductor base substrate;
an electrically conductive via partly or fully through the semiconductor base substrate and exposed at the back side of the microelectronic structure;
a dielectric layer having a first portion extending over the semiconductor base substrate and a second portion extending from the first portion along a portion of the electrically conductive via;
an insulating layer over the first portion of the dielectric layer, wherein the second portion of the dielectric layer is between the insulating layer and the portion of the electrically conductive via; and
a bonding surface at the back side of the microelectronic structure at least partially defined by an exposed end portion of the electrically conductive via, and a nonconductive bonding layer including a surface of the insulating layer.

3. The microelectronic structure of claim 2, wherein the bonding surface is a direct bonding surface.

4. The microelectronic structure of claim 3, wherein the insulating layer is activated at the bonding surface.

5. The microelectronic structure of claim 2, wherein the dielectric layer comprises a diffusion barrier.

6. The microelectronic structure of claim 2, wherein the nonconductive bonding layer further comprises a surface of the second portion of the dielectric layer.

7. A bonded structure comprising:
the microelectronic structure of claim 2; and
a second substrate having a front side and a back side, the front side including a nonconductive bonding layer and an exposed pad,
wherein the nonconductive bonding layer of the front side of the second substrate is bonded to the nonconductive bonding layer of the back side of the first substrate, and
wherein the exposed pad of the second substrate is bonded to the exposed end portion of the electrically conductive via.

8. The bonded structure of claim 7, wherein the second substrate is hybrid bonded to the microelectronic structure, without an intervening adhesive.

9. The bonded structure of claim 7 wherein the exposed pad is embedded at least partially in the second substrate.

10. The bonded structure of claim 7, further comprising a second electrically conductive via partly or fully through a semiconductor material of the second substrate.

11. The bonded structure of claim 10, wherein the second electrically conductive via is in electrical communication with the exposed pad.

12. The bonded structure of claim 11, wherein the second electrically conductive via of the second substrate is in electrical communication with the electrically conductive via of the microelectronic structure.

13. A microelectronic structure having a back side, the microelectronic structure comprising:
a semiconductor base substrate;
an electrically conductive via partly or fully through the semiconductor base substrate and exposed at the back side of the microelectronic structure;
a first dielectric layer having a first portion extending over the semiconductor base substrate and a second portion extending from the first portion along a portion of the electrically conductive via;
a second dielectric layer having a first portion extending over the first portion of the first dielectric layer and a second portion extending from the first portion along the second portion of the first dielectric layer;
an insulating layer over the first portion of the second dielectric layer, wherein the second portion of the first dielectric layer and the second portion of the second dielectric layer are between the insulating layer and the portion of the electrically conductive via; and
a bonding surface at the back side of the microelectronic structure at least partially defined by an exposed end portion of the electrically conductive via, and a nonconductive bonding layer including a surface of the second portion of the first dielectric layer, a surface of the second portion of the second dielectric layer and a surface of the insulating layer.

14. The microelectronic structure of claim 13, wherein the bonding surface is a direct bonding surface.

15. The microelectronic structure of claim 13, wherein the first dielectric layer comprises a diffusion barrier.

16. The microelectronic structure of claim 13, wherein the second dielectric layer comprises silicon oxide.

17. The microelectronic structure of claim 13, wherein the second dielectric layer comprises a different material compared to the insulating layer.

18. The microelectronic structure of claim 13, wherein the second dielectric layer and the insulating layer comprise the same material.

19. The microelectronic structure of claim 13, wherein the second dielectric layer is in direct contact with the insulating layer.

20. The microelectronic structure of claim 13, wherein the second dielectric layer and the insulating layer have different residue stress characteristics.

21. The microelectronic structure of claim 13, wherein one of the second dielectric layer or insulating layer is in tension, and the other of the second dielectric layer or the insulating layer is in compression.

22. A bonded structure comprising:
the microelectronic structure of claim 13; and
a second substrate having a front side and a back side, the front side including a nonconductive bonding layer and an exposed pad,
wherein the nonconductive bonding layer on the front side of the second substrate is bonded to the nonconductive bonding layer on the back side of the first substrate, and
wherein the exposed pad of the second substrate is bonded to the exposed end portion of the electrically conductive via.
